(19) United States
(12) Patent Application Publication
(10) Pub. No.: US 2025/0309846 A1
(43) Pub. Date: Oct. 2, 2025

(54) PHASE COMPENSATION CIRCUIT AND AMPLIFIER INCLUDING THE SAME

(71) Applicant: ABLIC Inc., Nagano (JP)

(72) Inventors: Nao OTSUKA, Nagano (JP); Toshiyuki TSUZAKI, Nagano (JP); Minoru SANO, Nagano (JP)

(73) Assignee: ABLIC Inc., Nagano (JP)

(21) Appl. No.: 19/060,761

(22) Filed: Feb. 23, 2025

(30) Foreign Application Priority Data
Mar. 26, 2024 (JP) 2024-050132

(51) Int. Cl. H03F 3/45

(52) U.S. Cl. CPC H03F 3/45475; H03F 2200/165

(57) ABSTRACT

Provided is an amplifier. An amplifier includes a differential amplifier; and a phase compensation circuit including an input port and an output port. The phase compensation circuit includes a transconductance amplifier including a first input port, a second input port, and an output port connected to an output node of the differential amplifier; and a high-pass filter (HPF) configured to pass, among signals output from the differential amplifier, a signal having a frequency at a specified frequency or higher and supply it to the first input port and the second input port.

### CROSS-REFERENCE TO RELATED APPLICATION

This application claims the priority benefits of Japanese application no. 2024-050132, filed on Mar. 26, 2024. The entirety of the above-mentioned patent application is hereby incorporated by reference herein and made a part of this specification.

### BACKGROUND

### Technical Field

The present invention relates to a phase compensation circuit and an amplifier including the same.

### Related Art

Generally, a differential amplifier and an amplifier including the same include a phase compensation circuit composed of capacitors and resistors for oscillation prevention. FIG. 4 show a differential amplifier 600 including a conventional phase compensation circuit. The conventional differential amplifier 600 includes a phase compensation circuit 624 between an error amplifier 622 and an output buffer 623. The phase compensation circuit 624 is composed of a capacitor 617, a resistor 618, and a transconductance amplifier 616. The phase compensation circuit 624 can prevent oscillation regardless of the capacitance of an output capacitor connected to an output port 621 by amplifying and feeding back the current flowing through the capacitor 617 by the transconductance amplifier 616 connected to both ends of the resistor 618.

However, in the differential amplifier 600 including the conventional phase compensation circuit 624, since the frequency at which an open loop gain is 1, that is, 0 (zero) dB, is low, the response speed of the output signal relative to the input signal is slow.

### SUMMARY

The present invention provides a phase compensation circuit capable of preventing oscillation regardless of the capacitance value of the output capacitor with a fast response speed, and an amplifier including the same.

A phase compensation circuit according to one aspect of the present invention includes: a first input port; a second input port; an output port connected to the first input port; a high-pass filter including a first input node connected to the first input port, a second input node connected to the second input port, a first output node, and a second output node connected to the second input node, the high-pass filter being configured to pass, among input signals, a signal having a frequency at a specified frequency or higher; and a transconductance amplifier including a first input node connected to the first output node of the high-pass filter, a second input node connected to the second output node of the high-pass filter, and an output node connected to the output port.

An amplifier according to one aspect of the present invention includes a differential amplifier including an output node; and a phase compensation circuit including an input port connected to the output node of the differential amplifier and an output port connected to the output node of the differential amplifier. The phase compensation circuit includes: a transconductance amplifier including a first input port, a second input port, and an output port connected to the output node of the differential amplifier; and a high-pass filter configured to pass, among signals output from the output node of the differential amplifier, a signal having a frequency at a specified frequency or higher and supply it to the first input port and the second input port of the transconductance amplifier.

According to the phase compensation circuit of the present invention and the amplifier including the same, it is possible to achieve a fast response speed and prevent oscillation regardless of the capacitance value of the output capacitor.

### BRIEF DESCRIPTION OF THE DRAWINGS

FIG. 1 is a circuit diagram illustrating an amplifier according to an embodiment of the present invention.

FIG. 2 is a circuit diagram illustrating another example of the phase compensation circuit according to the present embodiment.

FIG. 3 is a circuit diagram illustrating another example of the phase compensation circuit according to the present embodiment.

FIG. 4 is a circuit diagram illustrating a differential amplifier including a conventional phase compensation circuit.

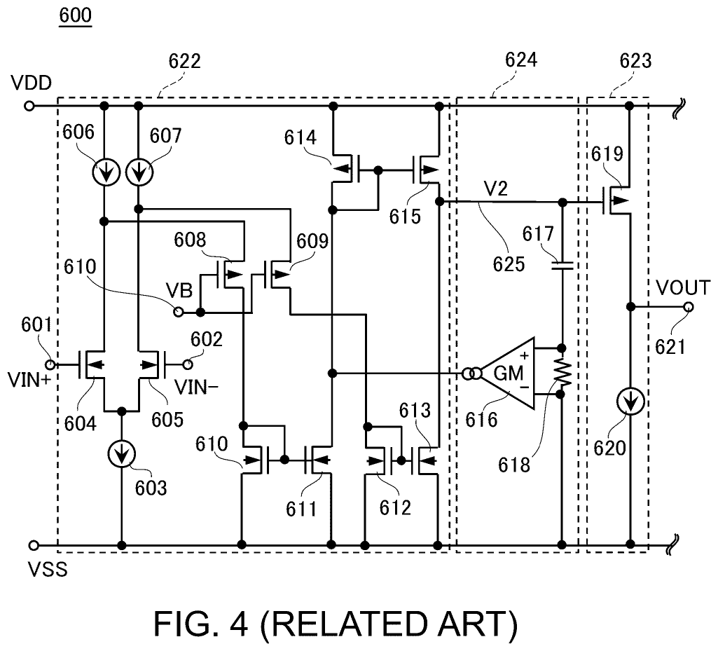

FIG. 5 is a graph showing the frequency versus open loop gain and frequency versus phase of the amplifier according to the present embodiment and a comparative example.

### DESCRIPTION OF THE EMBODIMENTS

The phase compensation circuit and the amplifier including the same according to an embodiment of the present invention will be described below with reference to the drawings.

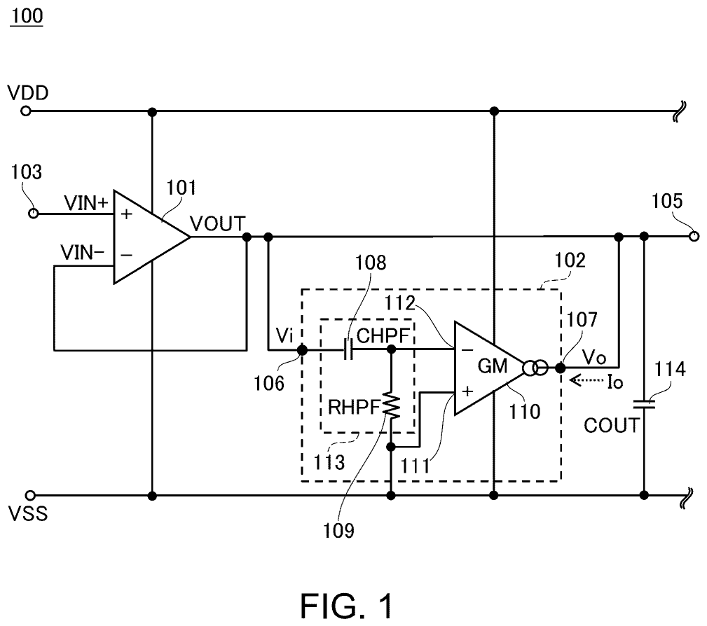

FIG. 1 is a circuit diagram illustrating a configuration example of an amplifier 100 serving as an amplifier according to an embodiment of the present invention.

The amplifier 100 includes a differential amplifier 101, a phase compensation circuit 102, an input port 103, an output port 105, and an output capacitor 114. The phase compensation circuit 102 includes a capacitor 108, a resistor 109, and a transconductance amplifier 110. The capacitor 108 and the resistor 109 constitute a high-pass filter (hereinafter referred to as “HPF”) 113. The differential amplifier 101 and the transconductance amplifier 110 are connected to VDD terminals and VSS terminals, respectively. Here, the VDD terminal is a power supply terminal supplying a voltage VDD, and the VSS terminal is a power supply terminal supplying a voltage VSS. The voltage VDD is a power supply voltage, and the voltage VSS is a power supply voltage different from the voltage VDD.

The differential amplifier 101 includes a non-inverting input port+ as a first input port, an inverting input port− as a second input port, and an output port serving as an output node of the differential amplifier 101. The non-inverting input port+ is connected to the input port 103, and the output port of the differential amplifier 101 is connected to the output port 105 (VOUT) of the amplifier 100. Additionally, the differential amplifier 101 has its output port and inverting input port-shorted, forming a voltage follower. An input port 106 (Vi) and an output port 107 (Vo) of the phase compensation circuit 102 are both connected to the output port of the differential amplifier 101 and the output port 105. An inverting input port 112 of the transconductance amplifier 110 is connected to the output port of the HPF 113, and a non-inverting input port 111 is connected to the VSS terminal. The output port of the transconductance amplifier 110 corresponds to the output port 107 (Vo) and is connected to the output port 105 (VOUT) of the differential amplifier 101.

The operation of the phase compensation circuit 102 will be described. The description will be given for the case where the voltage VOUT fluctuates steeply upward. Among the voltage signals received by the input port 106 (Vi), the voltage signal having a frequency at a specified frequency or higher, such as the cutoff frequency of the HPF 113, passes through the HPF 113 and is received by the inverting input port 112 of the transconductance amplifier 110. In response to the input voltage from the inverting input port 112 rising, the transconductance amplifier 110 sinks a current obtained by multiplying an input voltage from the inverting input port 112 by a transconductance GM from the output port 107 (Vo) towards the VSS terminal side. As described above, the phase compensation circuit 102 operates on the voltage VOUT that was about to fluctuate steeply upward, so as to reduce the voltage. In other words, the phase compensation circuit 102 can function to prevent oscillation by monitoring the steep change in the voltage VOUT and temporarily reducing an output resistance of the output port 105 where the voltage VOUT is output.

The operation described above will now be expressed using mathematical equations.

$$Io = GM \times 2 π f \times RHPF / ( 1 + 2 π f \times CHPF \times RHPF ) \times Vi \qquad ( 1 )$$

From equation (1),

$$Zo = Vi / Io = ( 1 + 2 π f \times CHPF \times RHPF ) / ( 2 π f \times CHPF \times RHPF \times GM ) \qquad ( 2 )$$

Here, Io is the output current of the phase compensation circuit 102, GM is the transconductance of the transconductance amplifier 110, fis the frequency of the input signal, and Zo is the impedance of the phase compensation circuit 102 as seen from the output port 105 (VOUT) of the differential amplifier 101. As a result, at the output port 105 (VOUT) of the differential amplifier 101, there are three elements connected in parallel: the impedance Zo of the phase compensation circuit 102, an output resistance ROUT seen from the output port 105 other than the phase compensation circuit 102, and the output capacitor 114 (COUT) connected to the output port 105. A synthetic impedance Z of the three elements will be calculated.

First, a synthetic impedance ZR from the impedance Zo of the phase compensation circuit 102 and the output resistance ROUT seen from the output port 105 other than the phase compensation circuit 102 will be calculated.

$$\begin{matrix}ZR = Zo / / ROUT \\ = ROUT \times ( 1 + 2 π f \times CHPF \times RHPF ) / \\ [ 2 π f \times CHPF \times RHPF \times ( GM \times ROUT + 1 ) + 1 ] \\ = ROUT \times ( 1 + 2 π f \times CHPF \times RHPF ) / ( 2 π f \times GM \times CHPF \times RHPF \times ROUT + 1 )\end{matrix} \qquad ( 3 )$$

Note that since GM×ROUT>>+1, the term “+1” included in (GM×ROUT+1) is ignored (eliminated) in equation (3).

Next, the synthetic impedance Z of the above synthetic impedance ZR and the output capacitor 114 (COUT) will be calculated.

$$\begin{matrix}Z = ZR / / COUT \\ = ROUT \times ( 1 + 2 π f \times CHPF \times RHPF ) / \\ [ {( 2 π f )}^{2} \times CHPF \times RHPF \times COUT \times ROUT + \\ 2 π f \times ROUT \times ( COUT + GM \times CHPF \times RHPF ) + 1 ]\end{matrix} \qquad ( 4 )$$

As the first condition, the case where a capacitance value COUT of the output capacitor 114 is large (COUT>>GM×CHPF×RHPF) is taken into consideration. In this case, equation (4) becomes as follows.

$$\begin{matrix}Z = ROUT \times ( 1 + 2 π f \times CHPF \times RHPF ) / \\ [ {( 2 π f )}^{2} \times CHPF \times RHPF \times COUT \times ROUT + \\ 2 π f \times ROUT \times ( COUT + GM \times CHPF \times RHPF ) + 1 ] \\ = ROUT / ( 2 π f \times ROUT \times COUT + 1 )\end{matrix} \qquad ( 5 )$$

Note that since COUT>>+GM×CHPFχRHPF, in equation (5), the term “+GM×CHPF×RHPF” included in (COUT+GM×CHPF×RHPF) is ignored (eliminated).

From equation (5), in the case where the capacitance value COUT of the output capacitor 114 is large (COUT>>GM×CHPF×RHPF), the following pole is generated.

$$Fp2\_ 5 = 1 / ( 2 π \times ROUT \times COUT ) \qquad ( 6 )$$

In equation (6), the phase compensation circuit 102 does not function in the case where the capacitance value COUT of the output capacitor 114 is large. Thus, the phase compensation circuit 102 does not move the frequency of the pole to the low frequency side, and can maintain a state where the response speed of the output voltage is fast.

On the other hand, as the second condition, the case where the capacitance value COUT of the output capacitor 114 is small (COUT<<GM×CHPF×RHPF holds) is taken into consideration. In the case where COUT<<GM×CHPF×RHPF holds, equation (4) becomes as follows.

$$\begin{matrix}Z = ROUT \times ( 1 + 2 π f \times CHPF \times RHPF ) / \\ [ {( 2 π f )}^{2} \times CHPF \times RHPF \times COUT \times ROUT + \\ 2 π f \times ROUT \times ( COUT + GM \times CHPF \times RHPF ) + 1 ] \\ = ROUT \times ( 1 + 2 π f \times CHPF \times RHPF ) / \\ [ ( 2 π f \times GM \times CHPF \times RHPF \times ROUT + 1 ) \times ( 2 π f \times COUT / GM + 1 ) ]\end{matrix} \qquad ( 7 )$$

Note that since COUT<<GM×CHPF×RHPF, in equation (7), the term “COUT” included in (COUT+GM×CHPF×RHPF) is ignored (eliminated).

From equation (7), in the case where the capacitance value COUT of the output capacitor 114 is small (COUT<<GM×CHPF×RHPF holds), the following poles Fp2_5, Fp4_5 and zero point Fz_5 are generated.

$$Fp2\_ 5 = 1 / ( 2 π \times GM \times CHPF \times RHPF \times ROUT ) \qquad ( 8 )$$

$$Fz\_ 5 = 1 / ( 2 π \times CHPF \times RHPF ) \qquad ( 9 )$$

$$Fp4\_ 5 = 1 / [ 2 π \times ( 1 / GM ) \times COUT ] \qquad ( 10 )$$

Comparing equation (10) with the pole Fp2 (=1/(2×π×ROUT×COUT)) generated at an output node of the second stage in a general two-stage amplifier without a phase compensation circuit connected, it may be seen that “ROUT” in the right-hand term is replaced with “1/GM” (reciprocal of GM). This is an effect of including the transconductance amplifier 110. As mentioned above, the condition is that the capacitance value COUT of the output capacitor 114 is small, and ROUT>> (1/GM), so Fp2<<Fp4_5, and the pole by the output capacitor 114 (COUT) moves to the high frequency side.

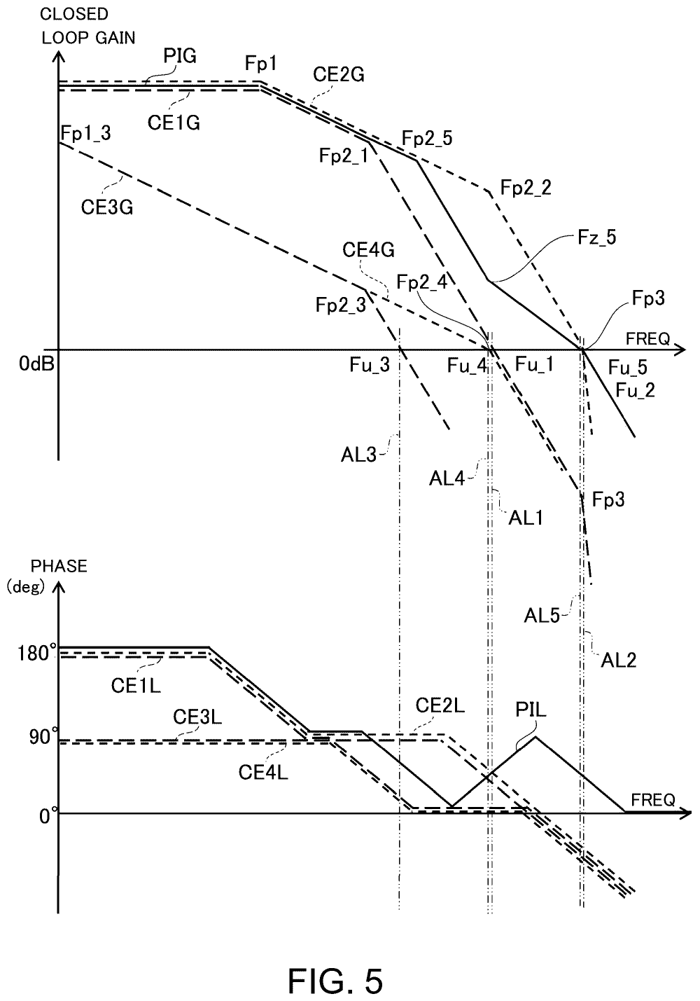

FIG. 5 is a graph showing the frequency characteristics of the open loop gain (upper half) and phase (lower half) with respect to frequency for the amplifier 100 according to the present embodiment and the first to fourth comparative examples. Note that the lines indicating each frequency characteristic are displayed slightly offset from one another in order to ensure visibility even in overlapping sections. Moreover, Fp4_5 in equation (10) has moved to the high frequency side and does not affect the open loop gain, so it is omitted from FIG. 5.

Here, a solid line PIG shown in the open loop gain (upper half) represents the open loop gain in the case where the capacitance value of the output capacitor 114 of the amplifier 100 is small (COUT<<GM×CHPF×RHPF holds). Dashed lines CE1G and CE2G represent the open loop gain in the case where the capacitance value of the output capacitor of a general two-stage amplifier is large (first comparative example) and small (second comparative example), respectively. Dashed lines CE3G and CE4G represent the open loop gain in the case where the capacitance value of the output capacitor of the amplifier described in Japanese Patent Application Laid-Open Publication No. 2011-151637 is large (third comparative example) and small (fourth comparative example), respectively. Moreover, Fu_1, Fu_2, Fu_3, Fu_4, and Fu_5 are the intersection points of the dashed lines CE1G to CE4G and the solid line PIG with the horizontal axis (straight line of OdB open loop gain), respectively. Furthermore, auxiliary lines AL1 to AL5 are straight lines parallel to the vertical axis passing through the intersection points Fu_1, Fu_2, Fu_3, Fu_4, and Fu_5, respectively.

Regarding the folding points, Fp1 and Fp2 are poles generated at an output node of the first stage and at the output node of the second stage of the amplifier, respectively. “Fp1_3” with the suffix “3” added to Fp1 is Fp1 in the third comparative example. “Fp2_1” to “Fp2_5” with suffixes 1 to 5 added to Fp2 correspond to the first to fourth comparative examples and the present embodiment (amplifier 100), respectively. In other words, Fp2_1 is Fp2 in the first comparative example, Fp2_4 is Fp2 in the fourth comparative example, and Fp2_5 is Fp2 in the present embodiment (amplifier 100). Fp3 is located on the higher frequency side (right side of the graph) than Fp1 and Fp2, with a frequency at the open loop gain of 1 (=0 dB) or lower. Fz_5 is the zero point of the amplifier 100.

A solid line PIL shown in the phase (lower half) represents the phase in the case where the capacitance value of the output capacitor 114 of the amplifier 100 is small (COUT<<GM×CHPF×RHPF holds). Dashed lines CE1L and CE2L represent the phase in the case where the capacitance value of the output capacitor of a general two-stage amplifier is large and small, respectively. Dashed lines CE3L and CE4L represent the phase in the case where the capacitance value of the output capacitor of the amplifier described in Japanese Patent Application Laid-Open Publication No. 2011-151637 is large and small, respectively.

First, the comparative examples will be described. In the case of the second comparative example and the fourth comparative example where the capacitance value of the output capacitor is small, from the relationship between the dashed lines CE2G and CE4G, the auxiliary lines AL2 and AL4, and the dashed lines CE2L and CE4L, both have an open loop gain of 1 and a phase margin of 0° or less already, thus oscillation cannot be prevented. Moreover, for the first comparative example where the capacitance value of the output capacitor is large, from the relationship between the dashed line CE1G, the auxiliary line AL1, and the dashed line CE1L, the first comparative example has an open loop gain of 1 and a phase margin of 0° or less already, and thus oscillation cannot be prevented. In contrast, in the case of the third comparative example where the capacitance value of the output capacitor is large, from the relationship between the dashed line CE3G, the auxiliary line AL3, and the dashed line CE3L, the open loop gain is 1 and the phase margin exceeds 0°, thus oscillation can be prevented, but the frequency is lower compared to other comparative examples. In other words, in the third comparative example, although oscillation is prevented, the response speed of the output signal to the input signal is slow.

On the other hand, the open loop gain (solid line PIG) of the amplifier 100 according to the present embodiment may be reduced by the pole of Fp2_5 in equation (8), and the phase delay may be restored by the zero point of Fz_5 in equation (9). Moreover, as may be seen from the relationship between the solid line PIG, the auxiliary line AL5, and the solid line PIL shown in FIG. 5, an open loop gain is 1 and the phase margin exceeds 0°, preventing oscillation. Additionally, the frequency does not decrease as in the third comparative example (dashed line CE3G), and the response speed of the output signal to the input signal is faster compared to each of the exemplified comparative examples. In this way, the amplifier 100 including the phase compensation circuit 102 can prevent oscillation without slowing down the response speed of the output signal to the input signal, regardless of the capacitance value COUT of the output capacitor 114 connected to the output port 105.

Next, several configuration examples of the phase compensation circuit in the amplifier according to the present embodiment will be described.

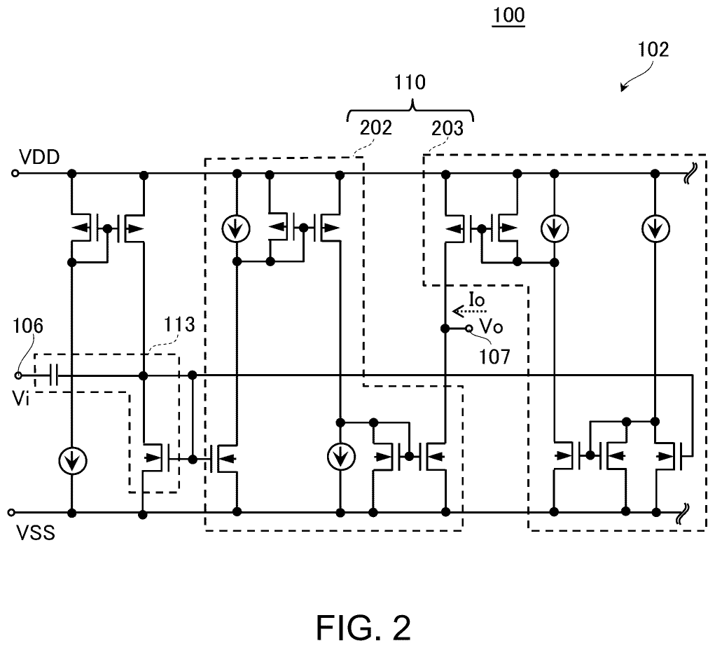

FIG. 2 is a specific circuit diagram of the phase compensation circuit 102 serving as the first configuration example of the phase compensation circuit in the amplifier 100.

The phase compensation circuit 102 includes a HPF 113 and a transconductance amplifier 110. The transconductance amplifier 110 is configured to have a circuit 202 configured to convert the voltage output from the HPF 113 into current and sink the current from the output port 107, and a circuit 203 configured to convert the voltage output from the HPF 113 into current and source the current to the output port 107. In the exemplary HPF 113 illustrated in FIG. 2, the resistive element (corresponding to the resistor 109 in FIG. 1) is an on-resistance of a transistor. The input transistor of the circuit 202 includes a gate receiving the voltage at both ends of the resistive element in the HPF 113.

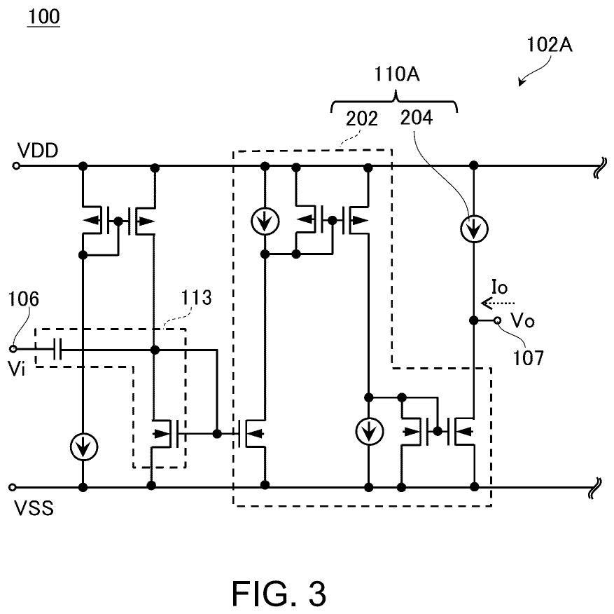

The present invention is not limited to the embodiments described above, and at the implementation stage, it may be implemented in various forms other than the examples described above, and various omissions, additions, substitutions, or modifications may be made within the scope of the invention. For example, the amplifier 100 may include a phase compensation circuit 102A (refer to FIG. 3 to be described later) instead of including the phase compensation circuit 102 (refer to FIG. 2).

FIG. 3 is a specific circuit diagram of the phase compensation circuit 102A serving as the second configuration example of the phase compensation circuit in the amplifier 100 according to the present embodiment.

The phase compensation circuit 102A differs from the phase compensation circuit 102 including the transconductance amplifier 110, in that it includes a transconductance amplifier 110A including, instead of the circuit 203, a current source 204 configured to supply a specified constant current, but it not substantially different in other aspects. In other words, in the phase compensation circuit 102A, the function of sourcing current to the output port 107 of the circuit 203 in the phase compensation circuit 102 is carried out by the current source 204. In the phase compensation circuit 102A, the upper limit of the current to be sourced to the output port 107 is restricted by the current source 204, the circuit configuration may be simplified compared to the phase compensation circuit 102.

The embodiments and their modifications are included within the scope and essence of the present invention, as well as within the scope of the inventions described in the patent claims and their equivalents.

What is claimed is:

1. An amplifier comprising:
a differential amplifier including an output node; and
a phase compensation circuit including an input port connected to the output node of the differential amplifier and an output port connected to the output node of the differential amplifier,
the phase compensation circuit including:
a transconductance amplifier including a first input port, a second input port, and an output port connected to the output node of the differential amplifier; and
a high-pass filter configured to pass, among signals output from the output node of the differential amplifier, a signal having a frequency at a specified frequency or higher and supply it to the first input port and the second input port of the transconductance amplifier.

2. The amplifier according to claim 1,
wherein the transconductance amplifier comprises:
a first circuit configured to convert a voltage output from the high-pass filter into current and sink a current from the output port of the transconductance amplifier; and
a second circuit configured to convert the voltage output from the high-pass filter into current and source the current from the output port of the transconductance amplifier.

3. The amplifier according to claim 1,
wherein the transconductance amplifier comprises:
a circuit configured to convert a voltage output from the high-pass filter into current and sink a current from the output port of the transconductance amplifier; and
a current source configured to source the current from the output port of the transconductance amplifier.

4. A phase compensation circuit, comprising:
a first input port;
a second input port;
an output port connected to the first input port;
a high-pass filter including a first input node connected to the first input port, a second input node connected to the second input port, a first output node, and a second output node connected to the second input node, the high-pass filter being configured to pass, among input signals, a signal having a frequency at a specified frequency or higher; and
a transconductance amplifier including a first input node connected to the first output node of the high-pass filter, a second input node connected to the second output node of the high-pass filter, and an output node connected to the output port.
